(19) United States
(12) Patent Application Publication
(10) Pub. No.: US 2020/0227499 A1
(43) Pub. Date: Jul. 16, 2020

(54) ORGANIC LIGHT EMITTING DIODE DISPLAY AND METHOD OF MANUFACTURING THEREOF

(71) Applicant: Shenzhen China Star Optoelectronics Semiconductor Display Technology Co., Ltd., Shenzhen (CN)

(72) Inventors: Jia TANG, Shenzhen (CN); Jangsoon IM, Shenzhen (CN)

(73) Assignee: Shenzhen China Star Optoelectronics Semiconductor Display Technology Co., Ltd., Shenzhen (CN)

(21) Appl. No.: 16/492,156

(22) PCT Filed: Apr. 1, 2019
(86) PCT No.: PCT/CN2019/080727

§ 371 Date: Sep. 9, 2019

(30) Foreign Application Priority Data
Jan. 16, 2019 (CN) 201910041369.X

(51) Int. Cl. H01L 27/32

(52) U.S. Cl. CPC H01L 27/3265; H01L 27/322; H01L 27/3246; H01L 2227/323; H01L 27/3262; H01L 27/3272; H01L 27/3258

(57) ABSTRACT

An organic light emitting diode (OLED) display panel and a method of manufacturing thereof are provided. The display panel includes: a substrate including a color film layer and a first transparent conductive layer; the first transparent conductive layer including a first region and a second region; an active region including a first active region and a second active region, the first active region is disposed above the first region, and the second active region is disposed above the second region; a gate lamination layer, an interlayer dielectric layer, a second transparent conductive layer, a planarization layer, an anode and a pixel defining layer disposed on the second active region.

### BACKGROUND OF APPLICATION

### Field of Application

The present application relates to the field of display technologies, and in particular, to an organic light emitting diode (OLED) display and a method for manufacturing thereof.

### Description of Prior Art

With the development of display technology, the organic light emitting diode (OLED) displays have made significant progress. OLED products have attracted more and more attention and application due to their advantages, such as light weight, fast response times, wide viewing angles, high contrast, and flexibility. OLED products are mainly used in mobile phones, tablets, TVs, and other display technology fields.

### Technical Problem

As panels increases in size, resistance of signal lines becomes non-negligible, resulting in an increase in a voltage drop phenomenon which leads to uneven brightness of the display panels and restricts the mass production of large-sized OLED display panels. Therefore, there is an urgent need to solve this problem.

### SUMMARY OF APPLICATION

The application provides an organic light emitting diode (OLED) display panel and a manufacturing method thereof to increase the capacitance of the OLED panel.

To solve the above problems, the present application provides an OLED display panel including:

a substrate;

a first transparent conductive layer disposed on the substrate, the first transparent conductive layer including a first region and a second region; the first region corresponding to a region for forming a color film layer and the second region corresponding to a region for forming a gate lamination layer;

a first buffer layer covering the first transparent conductive layer;

an active region disposed on the first buffer layer;

the gate lamination layer disposed on the active region;

an interlayer dielectric layer covering the first buffer layer, the active region, and the gate lamination layer, the interlayer dielectric layer having a plurality of via holes;

a second transparent conductive layer disposed on the interlayer dielectric layer, wherein the second transparent conductive layer covers the active region, and realizes electrical connections of source and drain regions through the via holes;

a planarization layer covering the interlayer dielectric layer and the second transparent conductive layer;

the color film layer disposed on the planarization layer, the color film layer is disposed on the first region;

a second buffer layer covering the color film layer and the planarization layer;

an anode disposed on the second buffer layer;

a pixel defining layer exposing the anode; and

a light emitting structure covering the pixel defining layer and the anode; wherein

the active region includes a first active region and a second active region, the first active region is disposed above the first region and the second active region is disposed above the second region.

According to one aspect of the application, a projection of the color film layer on a horizontal plane, a projection of the first region on a horizontal plane, and a projection of the first active region on a horizontal plane overlap.

According to one aspect of the application, the display panel further includes a light shielding metal layer between the first transparent conductive layer and the first buffer layer, a projection of the light shielding metal layer on a horizontal plane overlaps with a projection of the second active region on a horizontal plane.

According to one aspect of the application, the display panel further includes a metal layer disposed on the second transparent conductive layer, a projection of the metal layer on a horizontal plane overlaps with a projection of the second active region on a horizontal plane.

According to one aspect of the application, material forming the metal layer is a light shielding metal.

The present application provides an OLED display panel, including:

a substrate;

a first transparent conductive layer disposed on the substrate, the first transparent conductive layer including a first region and a second region; the first region corresponding to a region for forming a color film layer and the second region corresponding to a region for forming a gate lamination layer;

a first buffer layer covering the first transparent conductive layer;

an active region disposed on the first buffer layer;

the gate lamination layer disposed on the active region;

an interlayer dielectric layer covering the first buffer layer, the active region, and the gate lamination layer, the interlayer dielectric layer having a plurality of via holes;

a second transparent conductive layer disposed on the interlayer dielectric layer, wherein the second transparent conductive layer covers the active region, and realizes electrical connections of source and drain regions through the via holes;

a planarization layer covering the interlayer dielectric layer and the second transparent conductive layer;

the color film layer disposed on the planarization layer, the color film layer is disposed on the first region;

a second buffer layer covering the color film layer and the planarization layer;

an anode disposed on the second buffer layer;

a pixel defining layer exposing the anode; and

a light emitting structure covering the pixel defining layer and the anode.

According to one aspect of the application, the active region includes a first active region and a second active region, the first active region is disposed above the first region and the second active region is disposed above the second region.

According to one aspect of the application, a projection of the color film layer disposed on a horizontal plane, a projection of the first region disposed on a horizontal plane, and a projection of the first active region disposed on a horizontal plane overlap.

According to one aspect of the application, the display panel further includes a light shielding metal layer between the first transparent conductive layer and the first buffer layer, a projection of the light shielding metal layer disposed on a horizontal plane overlaps with a projection of the second active region disposed on a horizontal plane.

According to one aspect of the application, the display panel further includes a metal layer disposed on the second transparent conductive layer, a projection of the metal layer on a horizontal plane overlaps with a projection of the second active region on a horizontal plane.

According to one aspect of the application, the material forming the metal layer is a light shielding metal.

The present application further provides a method of manufacturing an OLED display panel, including the steps of:

providing a substrate;

forming a first transparent conductive layer disposed on the substrate, wherein the first transparent conductive layer includes a first region and a second region, the first region is used to form a color film layer, and the second region is used to form a gate lamination layer;

forming a first buffer layer covering the first transparent conductive layer;

forming an active region disposed on the first buffer layer;

forming the gate lamination layer over the active region;

forming an interlayer dielectric layer covering the first buffer layer, the active region, and the gate lamination layer, the interlayer dielectric layer having a plurality of via holes;

forming a second transparent conductive layer disposed on the interlayer dielectric layer, wherein the second transparent conductive layer is disposed above the first region and the second region, and realizes electrical connections of source and drain regions through the via holes;

forming a planarization layer covering the interlayer dielectric layer and the second transparent conductive layer;

forming the color film layer disposed on the planarization layer, the color film layer is disposed over the first region;

forming a second buffer layer covering the color film layer and the planarization layer;

forming an anode disposed on the second buffer layer;

forming a pixel defining layer exposing the anode; and

forming a light emitting structure covering the pixel defining layer and the anode.

According to one aspect of the application, the active region includes a first active region and a second active region, the first active region is disposed above the first region and the second active region is disposed above the second region.

According to one aspect of the application, a projection of the color film layer on a horizontal plane, a projection of the first region on a horizontal plane, and a projection of the first active region on a horizontal plane overlap.

According to one aspect of the application, after forming the first transparent conductive layer, the method further includes the following steps:

forming a light shielding metal layer covering the first transparent conductive layer;

patterning the light shielding metal layer, so that its projection on a horizontal plane overlaps with a projection of the second active region on a horizontal plane.

According to one aspect of the application, the method of patterning the light shielding metal layer and the first transparent conductive layer includes:

providing a mask having a first pattern for forming the first transparent conductive layer and a second pattern for forming the light shielding metal layer;

forming a photoresist covering the light shielding metal layer and the first transparent conductive layer, the photoresist having a first thickness;

the photoresist is patterned by the mask to form a first photoresist over the first transparent conductive layer and a second photoresist over the light shielding metal layer, the thickness of the first photoresist is less than the thickness of the second photoresist;

the light shielding metal layer and the first transparent conductive layer are patterned by using the first photoresist and the second photoresist as a mask.

According to one aspect of the application, the first pattern and the second pattern of the mask have different transmittances, and the transmittance of the first pattern is smaller than the transmittance of the second pattern.

According to one aspect of the application, after forming the second transparent conductive layer, the method further includes the steps of:

forming a metal layer over the second transparent conductive layer, a projection of the metal layer on a horizontal plane overlaps with a projection of the second active region on a horizontal plane.

According to one aspect of the application, the material forming the metal layer is a light shielding metal.

### Beneficial Effect

The OLED display panel provided by the present application has a first transparent conductive layer disposed on the base plate, a first active region disposed on the first transparent conductive layer, and a second transparent conductive layer disposed on the first active region. The first transparent conductive layer, the first active region and the second transparent conductive layer are respectively separated by a buffer layer and an interlayer dielectric layer, thereby forming a three-layer parallel capacitor structure. The present application can effectively increase the capacitance of the display panel and eliminate the pressure drop phenomenon.

### BRIEF DESCRIPTION OF DRAWINGS

In order to describe clearly the embodiment in the present disclosure or the prior art, the following will introduce the drawings for the embodiment shortly. Obviously, the following description is only a few embodiments, for the common technical personnel in the field it is easy to acquire some other drawings without creative work.

FIG. 1 to FIG. 11 are schematic structural diagrams of an organic light emitting diode (OLED) display panel in different process steps in an embodiment of the present application.

### DETAILED DESCRIPTION OF PREFERRED EMBODIMENTS

Description of following embodiment, with reference to accompanying drawings, is used to exemplify specific embodiments which may be carried out in the present disclosure. Directional terms mentioned in the present disclosure, such as “top”, “bottom”, “front”, “back”, “left”, “right”, “inside”, “outside”, “side”, etc., are only used with reference to orientation of the accompanying drawings. Therefore, the directional terms are intended to illustrate, but not to limit, the present disclosure. In the drawings, components having similar structures are denoted by same numerals.

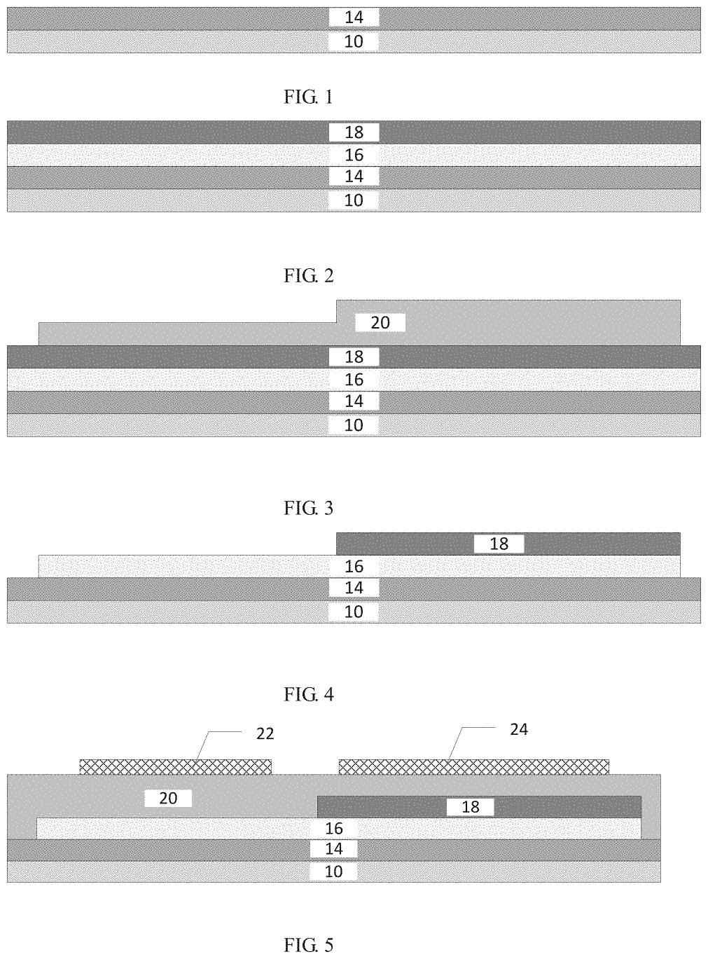

The application provides an organic light emitting diode (OLED) display panel and a manufacturing method thereof to increase the capacitance of the OLED panel. The application will be described in detail below with reference to the accompanying drawings. Specifically, referring to FIG. 1 to FIG. 11, FIG. 1 to FIG. 11 are schematic structural diagrams of an OLED display panel in different process steps in an embodiment of the present application.

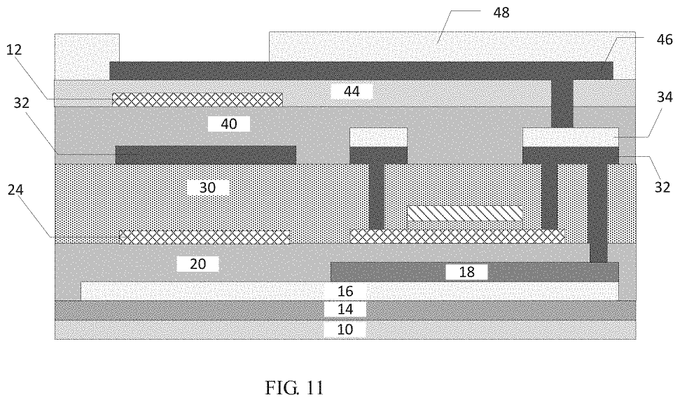

As shown in FIG. 11, the present application provides an OLED display panel including:

a substrate 10;

a first transparent conductive layer 16 disposed on the substrate 10, the first transparent conductive layer 16 including a first region and a second region. The first region corresponds to a region for forming a color film layer and the second region corresponds to a region for forming a gate lamination layer;

a first buffer layer 20 covering the first transparent conductive layer 16;

an active region 24 disposed on the first buffer layer 20. The active region 24 includes a first active region and a second active region, the first active region is disposed above the first region, and the second active region is disposed above the second region;

the gate lamination layer disposed on the active region 24;

an interlayer dielectric layer 30 covering the first buffer layer 20, the active region 24, and the gate lamination layer, the interlayer dielectric layer 30 having a plurality of via holes;

a second transparent conductive layer 32 disposed on the interlayer dielectric layer 30, wherein the second transparent conductive layer 32 covers the active region 24, and realizes electrical connections of source and drain regions through the via holes;

a planarization layer 40 covering the interlayer dielectric layer 30 and the second transparent conductive layer 32;

the color film layer 12 disposed on the planarization layer 40, the color film layer 12 is disposed on the first region;

a second buffer layer 44 covering the color film layer 12 and the planarization;

an anode 46 disposed on the second buffer 44 layer;

a pixel defining layer 48 exposing the anode 46; and

a light emitting structure covering the pixel defining layer 48 and the anode 46.

According to one aspect of the application, a projection of the color film layer 12 disposed on a horizontal plane, a projection of the first region disposed on a horizontal plane, and a projection of the first active region 24 disposed on a horizontal plane overlap.

Preferably, the display panel further includes a light shielding metal layer 18 between the first transparent conductive layer 16 and the first buffer layer 20, a projection of the light shielding metal layer 18 disposed on a horizontal plane overlaps with a projection of the second active region 24 disposed on a horizontal plane. Therefore, the first region of the first transparent conductive layer of the active region, the first active region, the second transparent conductive layer, the anode and the insulating layers between them constitute a plurality of capacitor structures connected in series to increase the capacitance of the OLED panel.

In the present embodiment, the display panel further includes a metal layer 34 disposed on the second transparent conductive layer 32, a projection of the metal layer 34 on a horizontal plane overlaps with a projection of the second active region 24 on a horizontal plane. Material forming the metal layer 34 is a light shielding metal.

The light shielding metal layer 18 and the metal layer 34 can block the light emitted by the light emitting structure from entering the light sensor under the display panel. Thereby, the interference of the light of the panel in the sensor can be eliminated.

The present application further provides a method of manufacturing an OLED display panel, and the method will be described in detail below.

First, providing a substrate 10, the substrate 10 can be a rigid substrate such as glass or a flexible substrate such as Polyimide (PI).

Preferably, after the substrate 10 is formed, the method further includes: forming a buffer layer 14 above the substrate 10 for improving an interface state between the substrate 10 and the first transparent conductive layer 16.

After that, referring to FIG. 2, forming the first transparent conductive layer 16 disposed on the substrate 10, wherein the first transparent conductive layer 16 includes a first region and a second region, the first region is used to form a color film layer 12, and the second region is used to form a gate lamination layer.

Preferably, after the transparent conductive layer 16 is formed, the method further includes: forming the light shielding metal layer 18 covering the first transparent conductive layer 16; and then patterning the light shielding metal layer 18 to make its projection on a horizontal plane overlaps with a projection of the second active region on a horizontal plane. Thereafter, the light shielding metal layer 18 and the first transparent conductive layer 16 are patterned, as shown in FIG. 4.

Specifically, providing a mask having a first pattern for forming the first transparent conductive layer 16 and a second pattern for forming the light shielding metal layer.

Forming a photoresist covering the light shielding metal layer and the first transparent conductive layer 16, the photoresist having a first thickness. The photoresist is patterned by the mask to form a first photoresist over the first transparent conductive layer 16 and a second photoresist over the light shielding metal layer, the thickness of the first photoresist is less than the thickness of the second photoresist. The light shielding metal layer and the first transparent conductive layer 16 are patterned by using the first photoresist and the second photoresist as a mask, as shown in FIG. 3.

In the present embodiment, the first pattern and the second pattern of the mask have different transmittance, and the transmittance of the first pattern is smaller than the transmittance of the second pattern. Specifically, it is implemented here by a half tone mask process. Wherein, the first pattern and the second pattern of the mask have different transmittances, and the transmittance of the first pattern is smaller than the transmittance of the second pattern. In practice, the transmittances of the first pattern and the second pattern are adjusted according to the thickness requirements of the photoresist. The half tone mask technology is a conventional technical means in the art and will not be described here.

After that, referring to FIG. 5, forming a first buffer layer 20 covering the first transparent conductive layer 16, and forming an active region 24 disposed on the buffer layer 20. Wherein the active region 24 includes a first active region and a second active region, the first active region is disposed above the first region, and the second active region is disposed above the second region.

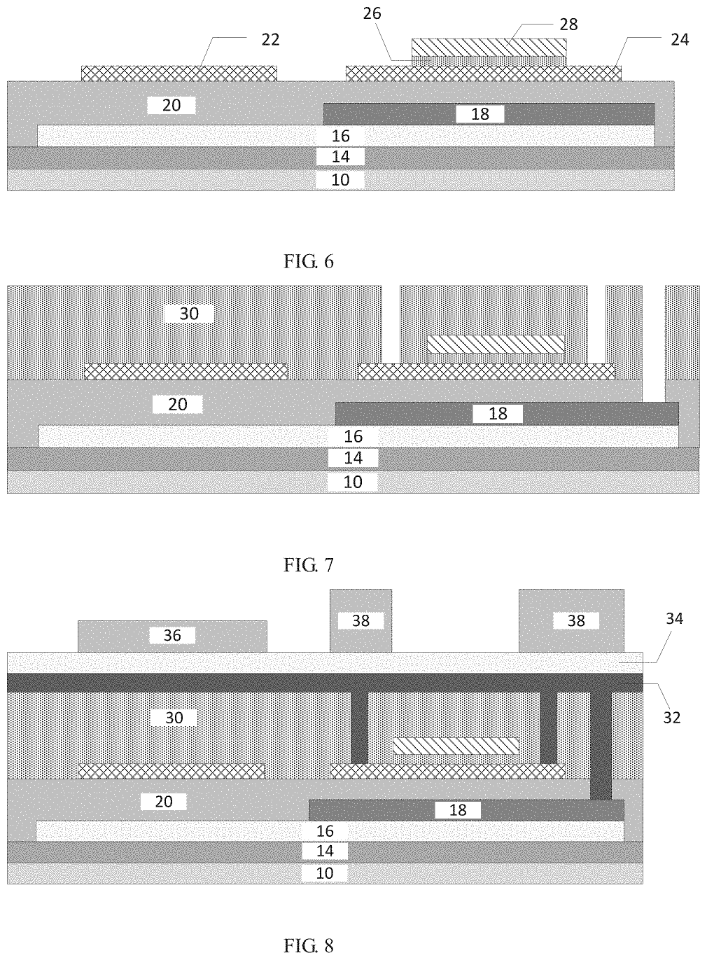

After that, referring to FIG. 6, forming the gate lamination layer over the active region 24. The gate lamination layer includes a gate dielectric layer 26 and a metal layer 28 in order from bottom to top.

After that, referring to FIG. 7, forming an interlayer dielectric layer 30 covering the second buffer layer 20, the first active region, and the gate lamination layer, the interlayer dielectric layer 30 having a plurality of via holes. Specifically, the via holes includes a first via hole exposing the source, a second via hole exposing a drain, and a third via hole exposing the entire metal layer 18.

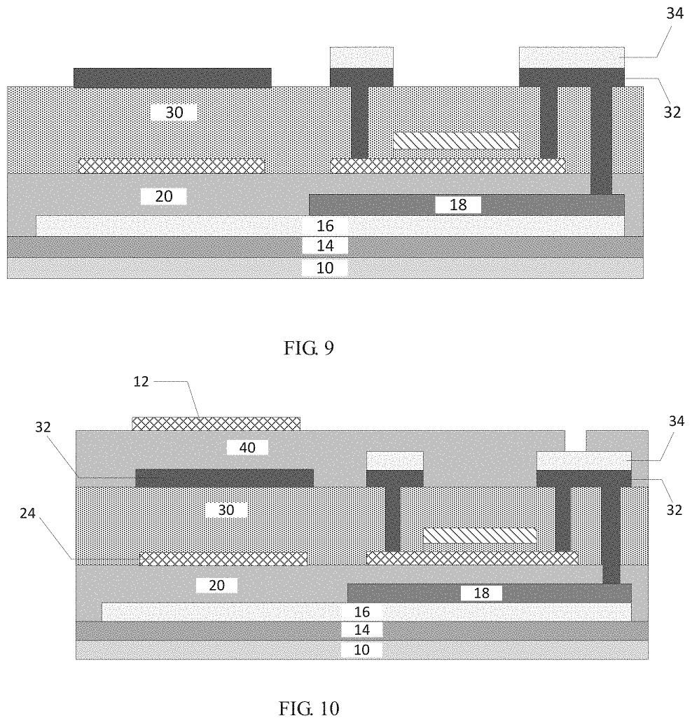

After that, referring to FIG. 8, forming a second transparent conductive layer 32 disposed on the interlayer dielectric layer 30, wherein the second transparent conductive layer 32 is disposed above the first region and the second region, and realizes electrical connections of source and drain regions through the via holes.

Preferably, referring to FIG. 8, after forming the second transparent conductive layer 32, the method further includes the steps of: forming a metal layer 34 over the second transparent conductive layer 32, a projection of the metal layer 34 on a horizontal plane overlaps with a projection of the second active region on a horizontal plane. The material forming the metal layer 34 is a light shielding metal, as shown in FIG. 9.

Thereafter, as shown in FIG. 10, the planarization layer 40 covering the interlayer dielectric layer 30 and the second transparent conductive layer 32, the color film layer 12 disposed on the planarization layer 40 are formed. The color film layer 12 is disposed above the first region. The color film layer 12 is composed of a regular arrangement of color films of red, green and blue colors. A projection of the color film layer 12 on a horizontal plane, a projection of the first region on a horizontal plane, and a projection of the first active region on a horizontal plane overlap.

Thereafter, as shown in FIG. 11, a second buffer layer 44 covering the color film layer 12 and the planarization layer 40, an anode 46 disposed above the second buffer layer 44 and an pixel definition layer 48 exposing the anode 46 are formed. Finally, an OLED display panel as shown in FIG. 11 is formed.

The OLED display panel provided by the present application has a first transparent conductive layer 16 disposed on the base plate, a first active region 24 disposed on the first transparent conductive layer 16, and a second transparent conductive layer 32 disposed on the first active region 24. The first transparent conductive layer 16, the first active region 24 and the second transparent conductive layer 32 are respectively separated by a buffer layer and an interlayer dielectric layer 30, thereby forming a three-layer parallel capacitor structure. The present application can effectively increase the capacitance of the display panel and eliminate the pressure drop phenomenon.

As is understood by persons skilled in the art, the foregoing preferred embodiments of the present disclosure are illustrative rather than limiting of the present disclosure. It is intended that they cover various modifications and that similar arrangements be included in the spirit and scope of the present disclosure, the scope of which should be accorded the broadest interpretation so as to encompass all such modifications and similar structures.

What is claimed is:

1. An organic light emitting diode (OLED) display panel comprising:
a substrate;
a first transparent conductive layer disposed on the substrate, the first transparent conductive layer comprising a first region and a second region; the first region corresponding to a region for forming a color film layer and the second region corresponding to a region for forming a gate lamination layer;
a first buffer layer covering the first transparent conductive layer;
an active region disposed on the first buffer layer;
the gate lamination layer disposed on the active region;
an interlayer dielectric layer covering the first buffer layer, the active region, and the gate lamination layer, the interlayer dielectric layer having a plurality of via holes;
a second transparent conductive layer disposed on the interlayer dielectric layer, wherein the second transparent conductive layer covers the active region, and realizes electrical connections of source and drain regions through the via holes;
a planarization layer covering the interlayer dielectric layer and the second transparent conductive layer;
the color film layer disposed on the planarization layer, the color film layer is disposed on the first region;
a second buffer layer covering the color film layer and the planarization;
an anode disposed on the second buffer layer;
a pixel defining layer exposing the anode; and
a light emitting structure covering the pixel defining layer and the anode;
wherein
the active region comprises a first active region and a second active region, the first active region is disposed above the first region and the second active region is disposed above the second region.

2. The OLED display panel according to claim 1, wherein a projection of the color film layer on a horizontal plane, a projection of the first region on a horizontal plane, and a projection of the first active region on a horizontal plane overlap.

3. The OLED display panel according to claim 1, wherein the display panel further comprises a light shielding metal layer between the first transparent conductive layer and the first buffer layer, a projection of the light shielding metal layer on a horizontal plane overlaps with a projection of the second active region on a horizontal plane.

4. The OLED display panel according to claim 1, wherein the display panel further comprises a metal layer disposed on the second transparent conductive layer, a projection of the metal layer on a horizontal plane overlaps with a projection of the second active region on a horizontal plane.

5. The OLED display panel according to claim 4, wherein material forming the metal layer is a light shielding metal.

6. An organic light emitting diode (OLED) display panel comprising:
a substrate;
a first transparent conductive layer disposed on the substrate, the first transparent conductive layer comprising a first region and a second region; the first region corresponding to a region for forming a color film layer and the second region corresponding to a region for forming a gate lamination layer;
a first buffer layer covering the first transparent conductive layer;
an active region disposed on the first buffer layer;
the gate lamination layer disposed on the active region;
an interlayer dielectric layer covering the first buffer layer, the active region, and the gate lamination layer, the interlayer dielectric layer having a plurality of via holes;
a second transparent conductive layer disposed on the interlayer dielectric layer, wherein the second transparent conductive layer covers the active region, and realizes electrical connections of source and drain regions through the via holes;
a planarization layer covering the interlayer dielectric layer and the second transparent conductive layer;
the color film layer disposed on the planarization layer, the color film layer is disposed on the first region;
a second buffer layer covering the color film layer and the planarization layer;
an anode disposed on the second buffer layer;
a pixel defining layer exposing the anode; and
a light emitting structure covering the pixel defining layer and the anode.

7. The OLED display panel according to claim 6, wherein the active region comprises a first active region and a second active region, the first active region is disposed above the first region and the second active region is disposed above the second region.

8. The OLED display panel according to claim 6, wherein a projection of the color film layer disposed on a horizontal plane, a projection of the first region disposed on a horizontal plane, and a projection of the first active region disposed on a horizontal plane overlap.

9. The OLED display panel according to claim 6, wherein the display panel further comprises a light shielding metal layer between the first transparent conductive layer and the first buffer layer, a projection of the light shielding metal layer disposed on a horizontal plane overlaps with a projection of the second active region disposed on a horizontal plane.

10. The OLED display panel according to claim 6, wherein the display panel further comprises a metal layer disposed on the second transparent conductive layer, a projection of the metal layer on a horizontal plane overlaps with a projection of the second active region on a horizontal plane.

11. The OLED display panel according to claim 10, wherein the material forming the metal layer is a light shielding metal.

12. A method of manufacturing an organic light emitting diode (OLED) display panel, comprising the steps of:
providing a substrate;
forming a first transparent conductive layer disposed on the substrate, wherein the first transparent conductive layer comprises a first region and a second region, the first region is used to form a color film layer, and the second region is used to form a gate lamination layer;
forming a first buffer layer covering the first transparent conductive layer;
forming an active region disposed on the first buffer layer;
forming the gate lamination layer over the active region;
forming an interlayer dielectric layer covering the first buffer layer, the active region, and the gate lamination layer, the interlayer dielectric layer having a plurality of via holes;
forming a second transparent conductive layer disposed on the interlayer dielectric layer, wherein the second transparent conductive layer is disposed above the first region and the second region, and realizes electrical connections of source and drain regions through the via holes;
forming a planarization layer covering the interlayer dielectric layer and the second transparent conductive layer;
forming the color film layer disposed on the planarization layer, the color film layer is disposed over the first region;
forming a second buffer layer covering the color film layer and the planarization layer;
forming an anode disposed on the second buffer layer;
forming a pixel defining layer exposing the anode; and
forming a light emitting structure covering the pixel defining layer and the anode.

13. The method of manufacturing the OLED display panel of claim 12, wherein the active region comprises a first active region and a second active region, the first active region is disposed above the first region and the second active region is disposed above the second region.

14. The method of manufacturing the OLED display panel of claim 12, wherein a projection of the color film layer on a horizontal plane, a projection of the first region on a horizontal plane, and a projection of the first active region on a horizontal plane overlap.

15. The method of manufacturing the OLED display panel of claim 12, wherein after forming the first transparent conductive layer, the method further comprises the following steps:
forming a light shielding metal layer covering the first transparent conductive layer;
patterning the light shielding metal layer, so that its projection on a horizontal plane overlaps with a projection of the second active region on a horizontal plane.

16. The method of manufacturing an OLED display panel of claim 12, wherein the method of patterning the light shielding metal layer and the first transparent conductive layer comprises:
providing a mask having a first pattern for forming the first transparent conductive layer and a second pattern for forming the light shielding metal layer;
forming a photoresist covering the light shielding metal layer and the first transparent conductive layer, the photoresist having a first thickness;
the photoresist is patterned by the mask to form a first photoresist over the first transparent conductive layer and a second photoresist over the light shielding metal layer, the thickness of the first photoresist is less than the thickness of the second photoresist;
the light shielding metal layer and the first transparent conductive layer are patterned by using the first photoresist and the second photoresist as a mask.

17. The method of manufacturing the OLED display panel according to claim 16, wherein, the first pattern and the second pattern of the mask have different transmittances, and the transmittance of the first pattern is smaller than the transmittance of the second pattern.

18. The method of manufacturing the OLED display panel according to claim 12, wherein, after forming the second transparent conductive layer, the method further comprises the steps of:
forming a metal layer over the second transparent conductive layer, a projection of the metal layer on a horizontal plane overlaps with a projection of the second active region on a horizontal plane.

19. The method of manufacturing the OLED display panel according to claim 18, wherein, the material forming the metal layer is a light shielding metal.
